(19) United States
(12) Patent Application Publication
(10) Pub. No.: US 2024/0423009 A1
(43) Pub. Date: Dec. 19, 2024

(54) LIGHT-EMITTING DEVICE, DISPLAY PANEL, AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Guangjun SONG, Beijing (CN); Hongbin ZHANG, Beijing (CN); Wenbin CHEN, Beijing (CN); Zhaowei YU, Beijing (CN); Qinhe WEI, Beijing (CN); Shuang LIN, Beijing (CN)

(21) Appl. No.: 18/704,475

(22) PCT Filed: May 12, 2023
(86) PCT No.: PCT/CN2023/093979

§ 371 Date: Apr. 25, 2024

(30) Foreign Application Priority Data
May 23, 2022 (CN) 202210561323.2

(51) Int. Cl. H10K 50/13; H10K 50/18; H10K 102/00

(52) U.S. Cl. CPC H10K 50/131; H10K 50/181; H10K 2102/351

(57) ABSTRACT

A light-emitting device, a display panel, and a display apparatus. The light-emitting device comprises a first sub-pixel region, a second sub-pixel region, and a third sub-pixel region. The light-emitting device comprises a cathode (10), an anode (30), and a light-emitting structure (20) provided between the cathode (10) and the anode (30). The light-emitting structure (20) comprises a light-emitting layer (21); and the light-emitting layer (21) comprises a single first light-emitting body (211) located in the first sub-pixel region, at least two second light-emitting bodies (212) located in the second sub-pixel region and arranged in a stacked manner, and at least two third light-emitting bodies (213) located in the third sub-pixel region and arranged in a stacked manner. The cathode (10) is used for providing electrons, and the anode (30) is used for providing holes.

### CROSS-REFERENCE TO RELATED APPLICATIONS

The present application is a U.S. National Phase Entry of International Application No. PCT/CN2023/093979 having an international filing date of May 12, 2023, which claims priority of Chinese Patent Application No. 202210561323.2, filed to the CNIPA on May 23, 2022 and entitled “Light-Emitting Device, Display Panel, and Display Apparatus”. Contents of the above-identified applications should be regarded as being incorporated herein by reference.

### TECHNICAL FIELD

Embodiments of the present disclosure relate to, but are not limited to, the field of display technologies, and specifically relate to a light-emitting device, a display panel, and a display apparatus.

### BACKGROUND

Organic Light-Emitting Diode (OLED) has the advantages of self-luminescence, relatively wide color gamut, relatively high contrast, and the like. In addition, because of its flexibility, it can also be used in some screen modes such as transparency, scroll, folding, curved surface, and the like. Therefore, OLED enjoys wide attention.

### SUMMARY

The following is a summary of subject matters described herein in detail. This summary is not intended to limit the protection scope of the claims.

Embodiments of the present disclosure provide a light-emitting device, a display panel, and a display apparatus. The technical schemes are as follows.

An embodiment of a first aspect of the present disclosure provides a light-emitting device having a first sub-pixel region, a second sub-pixel region and a third sub-pixel region. The light-emitting device includes a cathode, an anode, and a light-emitting structure provided between the cathode and the anode. The light-emitting structure includes a light-emitting layer including a single first light-emitting body located in the first sub-pixel region, at least two second light-emitting bodies located in the second sub-pixel region and arranged in a stacked manner, and at least two third light-emitting bodies located in the third sub-pixel region and arranged in a stacked manner. The cathode is used for providing electrons and the anode is used for providing holes.

In addition, a light-emitting device provided according to an embodiment of the present disclosure may also have the following additional technical features.

In some embodiments of the present disclosure, the electrons provided by the cathode and the holes provided by the anode recombine into excitons in the first light-emitting body so that the first light-emitting body emits light.

In some embodiments of the present disclosure, the first light-emitting body emits blue light, or the first light-emitting body emits red light, or the first light-emitting body emits green light.

In some embodiments of the present disclosure, the light-emitting layer further includes a charge production layer arranged between every two adjacent second light-emitting bodies and between every two adjacent third light-emitting bodies, the charge production layer is used for generating holes moving in a direction close to the cathode and electrons moving in a direction close to the anode under the action of an electric field between the cathode and the anode.

In some embodiments of the present disclosure, the charge production layer covers only the second light-emitting bodies and the third light-emitting bodies, and the charge production layer is separated from the first light-emitting body.

In some embodiments of the present disclosure, the charge production layer includes a body, a first hole transport layer, and a first electron transport layer, and the first hole transport layer is arranged on a first side of the body close to the cathode, and the first electron transport layer is arranged on a second side of the body close to the anode.

In some embodiments of the present disclosure, the charge production layer further includes: a hole block layer, or an electron block layer, or a hole block layer and an electron block layer. The hole block layer is arranged between a side of the first electron transport layer close to the anode and the second and third light-emitting bodies, and the electron block layer is arranged between a side of the first hole transport layer close to the cathode and the second and third light-emitting bodies.

In some embodiments of the present disclosure, the light-emitting structure further includes an electron injection layer arranged on a side of the cathode close to the light-emitting layer, a second electron transport layer arranged between the electron injection layer and the light-emitting layer, a hole injection layer arranged on a side of the anode close to the light-emitting layer, and a second hole transport layer arranged between the hole injection layer and the light-emitting layer.

In some embodiments of the present disclosure, the thickness of the first light-emitting body is greater than 5 nm and less than 100 nm.

In some embodiments of the present disclosure, the thickness of the first light-emitting body is greater than 15 nm and less than 30 nm.

In some embodiments of the present disclosure, the thickness of the first light-emitting body is identical to that of one of the at least two second light-emitting bodies.

In some embodiments of the present disclosure, the thickness of the first light-emitting body is identical to that of one of the at least two third light-emitting bodies.

In some embodiments of the present disclosure, the cathode is Mg:Ag, and the anode is indium tin oxide ITO/Ag/ITO arranged in a stacked manner.

An embodiment of a second aspect of the present disclosure provides a display panel including the light-emitting device provided according to the embodiment of the first aspect of the present disclosure.

An embodiment of a third aspect of the present disclosure provides a display apparatus including the display panel provided according to the embodiment of the second aspect of the present disclosure.

Other aspects of the present disclosure may be comprehended after the drawings and the detailed descriptions are read and understood.

### BRIEF DESCRIPTION OF DRAWINGS

FIG. 1 is a schematic diagram of a first structure of a light-emitting device provided by an embodiment of the present disclosure;

FIG. 2 is a comparison diagram of color deviation curves of different light-emitting devices provided by an embodiment of the present disclosure;

FIG. 3 is a schematic diagram of a second structure of a light-emitting device provided by an embodiment of the present disclosure;

FIG. 4 is a schematic diagram of a third structure of a light-emitting device provided by an embodiment of the present disclosure;

FIG. 5 is a schematic diagram of a fourth structure of a light-emitting device provided by an embodiment of the present disclosure;

FIG. 6 is a schematic diagram of a fifth structure of a light-emitting device provided by an embodiment of the present disclosure;

FIG. 7 is a schematic diagram of a sixth structure of a light-emitting device provided by an embodiment of the present disclosure; and

FIG. 8 is a schematic diagram of a seventh structure of a light-emitting device provided by an embodiment of the present disclosure.

### DETAILED DESCRIPTION

A clear and complete description of the technical schemes of embodiments of the present disclosure will be given below in conjunction with the accompanying drawings of the embodiments of the present disclosure. Like components are designated by like reference numerals. Apparently, the described embodiments are only a part of the embodiments of the present disclosure, not all of the embodiments. Based on the embodiments in the present disclosure, all other embodiments obtained by those of ordinary skill in the art based on the present disclosure fall within the scope of protection of the present disclosure.

Based on the same orientation understanding, in the description of the present disclosure, directional or positional relationships described by terms such as “center”, “length”, “width”, “height”, “upper”, “lower”, “front”, “rear”, “top”, “bottom”, “inner” and “outer” are directional or positional relationships as shown in the drawings, which are used for convenience in describing the present disclosure and simplifying the description, rather than indicating or implying that the apparatus or element referred to must have a specific orientation, is constructed or operated in the specific orientation, and thus should not be understood as limitation to the present disclosure.

Organic light-emitting diode (OLED) has many advantages such as self-luminescence, wide color gamut and high contrast. In addition, because of its flexibility, it can also be applied to transparent, rolled, folding, curved and other screen modes. Therefore, OLED enjoys wide attention. However, OLED also has some problems, such as low light-emitting efficiency or high voltage of its light-emitting devices, which leads to high power consumption and short life of the light-emitting devices, which is the bottleneck that urgently needs to be broken through in this field.

At present, the light-emitting body of the light-emitting device in OLED generally has a single-layer structure, the light-emitting device with such structure is called a single-layer device, its light-emitting efficiency is low, its life is short and its power consumption is high. In some technologies, a stacked device is proposed, which has light-emitting bodies arranged in a stacked manner. For example, each R/G/B monochrome of each pixel unit is designed to have two light-emitting bodies stacked on top of each other, which can better improve the efficiency and life of the device. However, due to the limitation of its own structure, the required cross-voltage of the stacked device is greater than that of a single-layer device with only light-emitting body arranged in a single layer, and a light-up voltage of a light-emitting body corresponding to each R/G/B monochrome of each pixel unit is about twice that of the light-emitting body of the single-layer device. Therefore, although the efficiency of the stacked device is higher, its actual power consumption benefit is not significant.

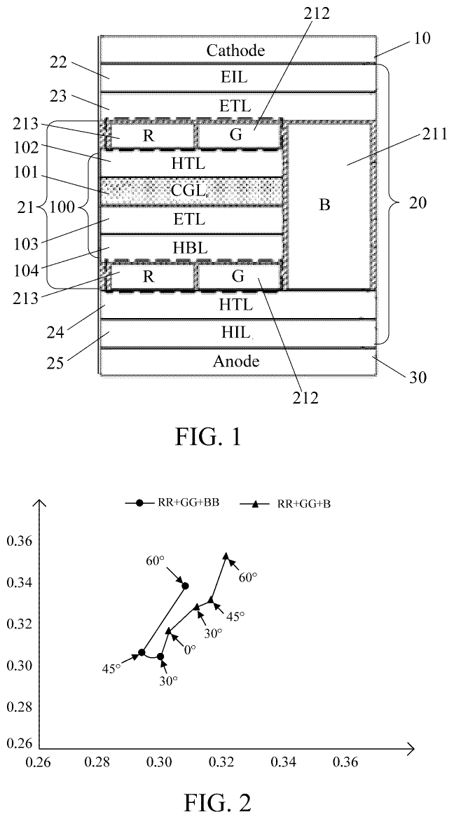

In view of this, as shown in FIG. 1, an embodiment of the first aspect of the present disclosure provides a light-emitting device having a first sub-pixel region, a second sub-pixel region, and a third sub-pixel region. The light-emitting device includes a cathode 10, an anode 30, and a light-emitting structure 20 provided between the cathode 10 and the anode 30. The light-emitting structure 20 includes a light-emitting layer 21, and the light-emitting layer 21 includes a single first light-emitting body 211 located in the first sub-pixel region, at least two second light-emitting bodies 212 located in the second sub-pixel region and arranged in a stacked manner, and at least two third light-emitting bodies 213 located in the third sub-pixel region and arranged in a stacked manner. The cathode 10 is used for providing electrons, and the anode 30 is used for providing holes.

In an example, the cathode 10 may be Mg:Ag, the anode 30 may be ITO (Indium-Tin Oxide)/Ag/ITO arranged in a stacked manner. The first light-emitting body 211, the second light-emitting body 212 and the third light-emitting body 213 may emit light of three different colors, such as red, green and blue, respectively under the power-on condition to meet the requirements of different products.

A light-emitting device according to an embodiment of the first aspect of the present disclosure includes a cathode 10, an anode 30, and a light-emitting structure 20 provided between the cathode 10 and the anode 30. The light-emitting structure 20 includes a light-emitting layer 21 including a single first light-emitting body 211 located in a first sub-pixel region, at least two second light-emitting bodies 212 located in a second sub-pixel region and arranged in a stacked manner, and at least two third light-emitting bodies 213 located in a third sub-pixel region and arranged in a stacked manner. That is, in a light-emitting device in an embodiment of the present disclosure, on the one hand, at least two second light-emitting bodies 212 are stacked in the second sub-pixel region, and at least two third light-emitting bodies 213 are stacked in the third sub-pixel region, so as to form a structure of a stacked device in the second sub-pixel region and the third sub-pixel region, thereby utilizing the structural advantages of the stacked device to improve the overall light-emitting efficiency and life of the light-emitting device. On the other hand, a first light-emitting body 211 arranged in a single-layer structure is provided in the first sub-pixel region, that is, a single-layer device structure is formed in the first sub-pixel region, so as to reduce the requirement on a light-up voltage of the first light-emitting body 211. Thus, the overall light-emitting efficiency and lifetime of the light-emitting device can be improved, and at the same time, the overall cross-voltage can be reduced, thereby reducing the power consumption of the light-emitting device.

In some embodiments of the present disclosure, electrons provided by the cathode 10 and holes provided by the anode 30 recombine into excitons in the first light-emitting body 211 so that the first light-emitting body 211 to emit blue light. As shown in FIG. 1, the first light-emitting body 211 provided in the form of a single-layer structure is a light-emitting body emitting blue light under the power-on condition (denoted by “B” in the figure), and “R” and “G” in the figure denote a light-emitting body emitting red light under the power-on condition and a light-emitting body emitting green light under the power-on condition, respectively. According to practical applications and experiments, it is found that when R, G and B are all arranged in a structure of laminated devices, a light-up voltage of B is especially high, which greatly increases the overall cross-voltage. Moreover, when the backplanes are all LTPS (Low Temperature Poly-Silicon), the measured life of the structure is as follows: the lives of only R and G are significantly improved, and the actual life of B is not much different from that when it is arranged in the structure of single-layer device. Therefore, by using the light-emitting body emitting blue light under the power-on condition as the first light-emitting body 211 arranged in the form of a single-layer structure, it is possible to improve the overall light-emitting efficiency and life of the light-emitting device while better reducing the overall cross-voltage, thereby further reducing the power consumption of the light-emitting device and improving the performance of the light-emitting device.

In some embodiments of the present disclosure, as shown in FIG. 1, the light-emitting layer 21 further includes a charge production layer 100 arranged between every two adjacent second light-emitting bodies 212 and between every two adjacent third light-emitting bodies 213 and configured for generating holes moving in a direction close to the cathode 10 and electrons moving in a direction close to the anode 30 under the action of an electric field between the cathode 10 and the anode 30. For example, as shown in FIG. 1, only two second light-emitting bodies 212 are stacked in the second sub-pixel region, and a charge production layer 100 is arranged between the two second light-emitting bodies 212, and holes generated by the charge production layer 100 and moved in a direction close to the cathode 10 and electrons supplied from the cathode 10 are recombined into excitons in a first of the second light-emitting bodies 212 located on one side of the charge production layer 100 close to the cathode 10, so that the first of the second light-emitting bodies 212 emit light. Electrons generated by the charge production layer 100 and moved in a direction close to the anode 30 and holes provided by the anode 30 are recombined into excitons in a second of the second light-emitting bodies 212 located on the other side of the charge production layer 100 close to the anode 30, so that the second of the second light-emitting bodies 212 emits light. Series connection is achieved between every two adjacent second light-emitting bodies 212 and every two adjacent third light-emitting bodies 213 by a charge production layer 100 to form a structure of a laminated device.

In some embodiments of the present disclosure, the charge production layer 100 covers only the second and third light-emitting bodies 212 and 213, and is separated from the first light-emitting body 211. For example, in the process of evaporation of the charge production layer 100, the first light-emitting body 211 may be isolated by using an FMM (Fine Metal Mask), and the FMM may be removed after the evaporation of the charge production layer 100 is completed, so that the charge production layer 100 obtained by evaporation only covers the second light-emitting bodies 212 and the third light-emitting bodies 213 and is separated from the first light-emitting body 211. In this way, the light-emitting efficiency of the first light-emitting body 211 arranged in a single-layer structure is improved, and low gray-scale crosstalk caused by the transverse leakage of the first light-emitting body 211 is reduced, and the phenomenon of accompanying light-emitting of the second light-emitting bodies 212 and the third light-emitting bodies 213 caused by the first light-emitting body 211 under the low gray-scale is improved, thereby improving the low gray-scale image quality.

In some embodiments of the present disclosure, as shown in FIG. 1, the charge production layer 100 includes a body (charge generation layer, CGL) 101, a first hole transport layer (HTL) 102, and a first electron transport layer (ETL) 103. The first hole transport layer 102 is arranged on a first side of the body 101 close to the cathode 10, and the first electron transport layer 103 is provided on a second side of the body 101 close to the anode 30. The holes generated by the body 101 are transmitted through the first hole transport layer 102 to the second light-emitting body 212 and the third light-emitting body 213 located close to the first side of the body 101. Electrons generated by the body 101 are transmitted through the first electron transport layer 103 to the second light-emitting body 212 and the third light-emitting body 213 located close to the second side of the body 101.

In some embodiments of the present disclosure, as shown in FIG. 1, the charge production layer 100 further includes a hole block layer (HBL) 104, or as shown in FIG. 8, the charge production layer 100 further includes an electron block layer (EBL) 111. In an exemplary embodiment, the charge production layer 100 further includes a hole block layer 104 and an electron block layer 111, the hole block layer 104 is arranged between a side of the first electron transport layer 103 close to the anode 30 and the second and third light-emitting bodies 212 and 213, and the electron block layer 111 is arranged between a side of the first hole transport layer 102 close to the cathode 10 and the second and third light-emitting bodies 212 and 213. By utilizing the hole block effect of the hole block layer 104 and/or the electron block effect of the electron block layer 111, the distribution of excitons in each layer of the second light-emitting body 212 and each layer of the third light-emitting body 213 can be adjusted, thereby improving the overall light-emitting effect.

In some embodiments of the present disclosure, as shown in FIG. 1, the light-emitting structure 20 further includes an electron injection layer (EIL) 22 arranged on a side of the cathode 10 close to the light-emitting layer 21, a second electron transport layer 23 arranged between the electron injection layer 22 and the light-emitting layer 21, a hole injection layer 25 arranged on a side of the anode 30 close to the light-emitting layer 21, and a second hole transport layer 24 arranged between the hole injection layer 25 and the light-emitting layer 21. Electrons generated by the cathode 10 are transmitted to the light-emitting layer 21 sequentially through the electron injection layer 22 and the second electron transport layer 23, and while holes generated by the anode 30 are transmitted to the light-emitting layer 21 sequentially through the hole injection layer 25 and the second hole transport layer 24, to provide charges for the first light-emitting body 211, at least part of the second light-emitting bodies 212 and at least part of the third light-emitting bodies 213 in the light-emitting layer 21, the charges are used for forming excitons.

In some embodiments of the present disclosure, the thickness of the first light-emitting body 211 is greater than 5 nm and less than 100 nm, in order to better adapt to a color deviation trajectory of a small viewing angle, improve the yellowing phenomenon of a large viewing angle, thereby improving the display effect. For example, a structure of a light-emitting device as shown in FIG. 1 is obtained by designing B as a first light-emitting body 211 in a single-layer device structure, and appropriately adjusting the film thickness of the first light-emitting body 211 so that the thickness of the first light-emitting body 211 is greater than 15 nm and less than 30 nm. The color deviation of a structure of the light-emitting device shown in FIG. 1 and provided by the embodiment of the present disclosure is fitted according to the color deviation data of a structure of the existing laminated device, to obtain a graph shown in FIG. 2. As can be seen from FIG. 2, the RR+GG+BB curve represents a color deviation curve of the existing laminated device structure, and a color deviation trajectory of a small viewing angle has no inflection point, and directly travels in the direction toward yellow of the upper right corner, which makes a large viewing angle of the actual product is visually yellow. The RR+GG+B curve represents a fitting color deviation curve of a structure of a light-emitting device as shown in FIG. 1 and provided by an embodiment of the present disclosure, and a color deviation trajectory of a small viewing angle has an obvious inflection point, and the yellowing tendency of a large viewing angle is restrained. Moreover, the thickness of the first light-emitting body 211 arranged in a single layer is greater than 5 nm and less than 100 nm, which is more in line with the color deviation trajectory of most products at present, and is helpful to improve the visual perception of human eyes.

A light-emitting device disclosed in an embodiment of the present disclosure may be a top-emitting type or a bottom-emitting type, which is not limited in the present disclosure. In addition, FIG. 1 only illustrates the structure of a light-emitting device in which B is provided as the first light-emitting body 211 in the form of a single-layer structure, G and R are provided as the second light-emitting bodies 212 and the third light-emitting bodies 213, respectively, and both G and R are provided in the form of a double-layer structure, respectively, and the thickness of B in FIG. 1 is also only schematic but not an actual thickness.

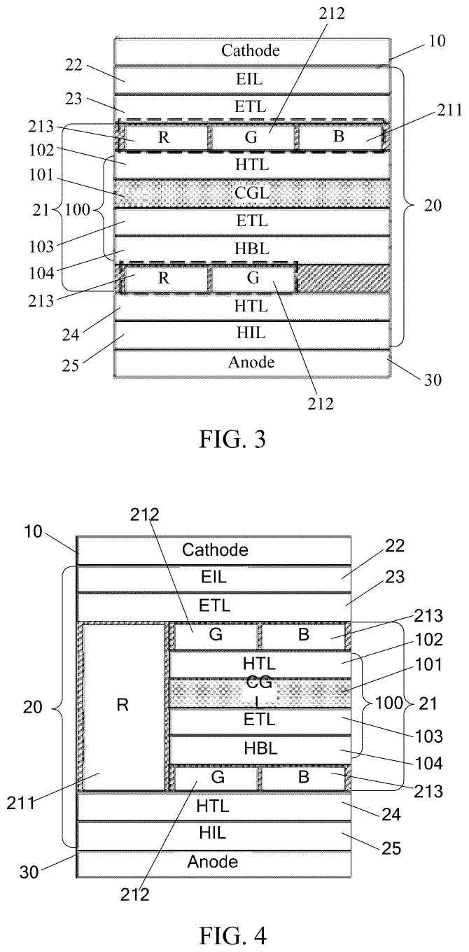

In some embodiments of the present disclosure, as shown in FIG. 3, the thickness of one first light-emitting body 211 arranged in a single layer can be identical to that of one of the layers (i.e., one of the light emitters) of the second light-emitting bodies 212 or the third light-emitting bodies 213 arranged in a stacked manner. In this scheme, the mask design does not need to be changed, and the equipment cost can be saved.

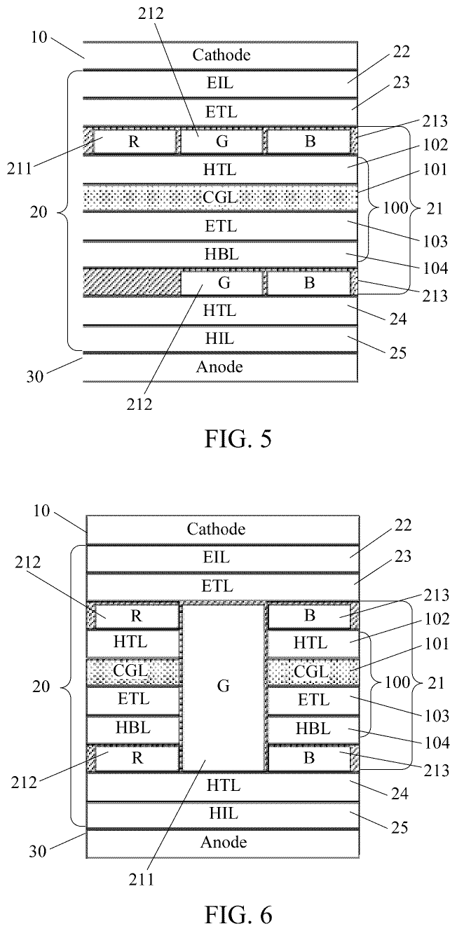

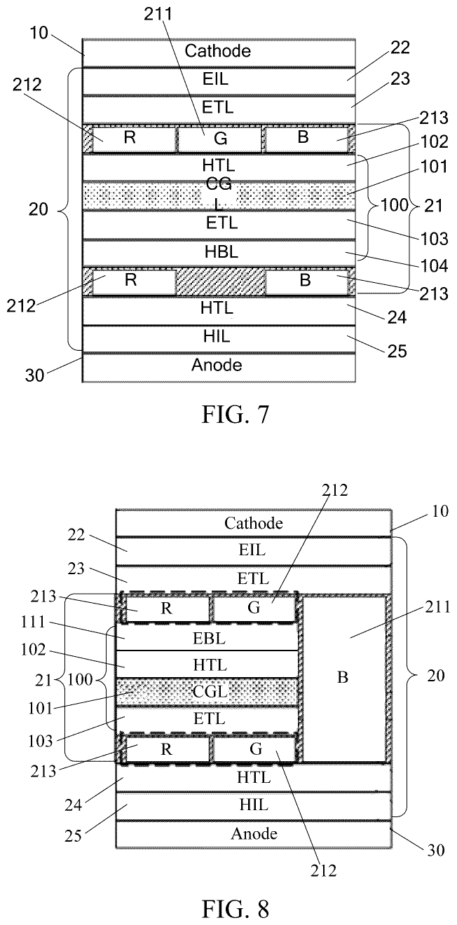

In some embodiments of the present disclosure, according to the actual efficiencies of R, G, B, a light-emitting body with higher actual efficiency among R, G, B can be selected as the first light-emitting body 211 and arranged in the form of a single layer structure to save material cost and simplify the fabrication process. For example, as shown in FIGS. 4 and 5, there are schematic diagrams of two structures of light-emitting devices in which R is selected as the first light-emitting body 211 arranged in the form of a single-layer structure, G and B are selected as the second light-emitting bodies 212 and the third light-emitting bodies 213, respectively, and both G and B are respectively arranged in the form of a double-layer structure. As shown in FIGS. 6 and 7, there are schematic diagrams of two structures of light-emitting devices in which G is selected as the first light-emitting body 211 arranged in the form of a single-layer structure, R and B are selected as the second light-emitting bodies 212 and the third light-emitting bodies 213, respectively, and both R and B are respectively arranged in the form of a double-layer structure.

An embodiment of a second aspect of the present disclosure provides a display panel including a light-emitting device provided according to an embodiment of the first aspect of the present disclosure.

According to the display panel provided by an embodiment of the second aspect of the present disclosure, a light-emitting device thereof includes a cathode 10, an anode 30, and a light-emitting structure 20 provided between the cathode 10 and the anode 30, the light-emitting structure 20 includes a light-emitting layer 21 including a single first light-emitting body 211 located in a first sub-pixel region, at least two second light-emitting bodies 212 located in a second sub-pixel region and arranged in a stacked manner, and at least two third light-emitting bodies 213 located in a third sub-pixel region and arranged in a stacked manner. That is, in a light-emitting device of an embodiment of the present disclosure, on the one hand, at least two second light-emitting bodies 212 are stacked in the second sub-pixel region, and at least two third light-emitting bodies 213 are stacked in the third sub-pixel region, so as to form a structure of a stacked device in the second sub-pixel region and the third sub-pixel region, thereby utilizing the structural advantages of the stacked device to improve the overall light-emitting efficiency and life of the light-emitting device. On the other hand, one first light-emitting body 211 in a single-layer structure is provided in the first sub-pixel region, that is, a single-layer device structure is formed in the first sub-pixel region, so as to reduce the requirement on a light-up voltage of the first light-emitting body 211. In this way, the overall light-emitting efficiency and lifetime of the light-emitting device can be improved, and at the same time, the overall cross-voltage can be reduced, thereby reducing the power consumption of the light-emitting device. It can be seen that the display panel provided by an embodiment of the second aspect of the present disclosure has better light-emitting performance.

An embodiment of a third aspect of the present disclosure provides a display apparatus including a display panel provided according to an embodiment of the second aspect of the present disclosure.

A display apparatus provided according to an embodiment of the third aspect of the present disclosure has a display panel including a light-emitting device, which includes a cathode 10, an anode 30, and a light-emitting structure 20 provided between the cathode 10 and the anode 30. The light-emitting structure 20 includes a light-emitting layer 21. The light-emitting layer 21 includes a single first light-emitting body 211 located in a first sub-pixel region, at least two second light-emitting bodies 212 located in a second sub-pixel region and arranged in a stacked manner, and at least two third light-emitting bodies 213 located in a third sub-pixel region and arranged in a stacked manner. That is, in a light-emitting device of an embodiment of the present disclosure, on the one hand, at least two second light-emitting bodies 212 are stacked in the second sub-pixel region, and at least two third light-emitting bodies 213 are stacked in the third sub-pixel region, so as to form a structure of a stacked device in the second sub-pixel region and the third sub-pixel region, thereby utilizing the structural advantages of the stacked device to improve the overall light-emitting efficiency and life of the light-emitting device. On the other hand, one first light-emitting body 211 in a single-layer structure is provided in the first sub-pixel region, that is, a single-layer device structure is formed in the first sub-pixel region, so as to reduce the requirement on a light-up voltage of the first light-emitting body 211. In this way, the overall light-emitting efficiency and lifetime of the light-emitting device can be improved, and at the same time, the overall cross-voltage can be reduced, thereby reducing the power consumption of the light-emitting device. It can be seen that the display panel of the display apparatus provided by an embodiment of the third aspect of the present disclosure has better light-emitting performance.

It should be noted that relational terms such as first and second are used herein only to distinguish one entity or operation from another and do not necessarily require or imply any such actual relationship or order between these entities or operations. Moreover, the terms “include”, “comprise” or any other variations thereof are intended to cover a non-exclusive inclusion, such that a process, method, article, or equipment that includes a series of elements includes not only those elements but also other elements which are not expressly listed, or further includes elements inherent to such a process, method, article, or equipment. An element defined by a statement “include one . . . ” does not exclude presence of additional identical elements in the process, method, article or equipment that includes the element, without more limitations.

Various embodiments of the present disclosure are described in a related manner, and the same and similar parts between the embodiments can be referred to each other with emphasis on the differences between each embodiment and other embodiments.

The above description is only preferred embodiments of the present disclosure and is not intended to limit the scope of protection of the present disclosure. Any modifications, equivalent substitutions, modifications, etc. made within the spirit and principles of the present disclosure are included in the scope of protection of the present disclosure.

1. A light-emitting device, having a first sub-pixel region, a second sub-pixel region, and a third sub-pixel region, wherein the light-emitting device comprises a cathode, an anode, and a light-emitting structure provided between the cathode and the anode, the light-emitting structure comprises a light-emitting layer comprising a single first light-emitting body located in the first sub-pixel region, at least two second light-emitting bodies located in the second sub-pixel region and arranged in a stacked manner, and at least two third light-emitting bodies located in the third sub-pixel region and arranged in a stacked manner, the cathode is used for providing electrons and the anode is used for providing holes.

2. The light-emitting device according to claim 1, wherein the electrons provided by the cathode and the holes provided by the anode recombine into excitons in the first light-emitting body so that the first light-emitting body emits light.

3. The light-emitting device according to claim 2, wherein the first light-emitting body emits blue light, or the first light-emitting body emits red light, or the first light-emitting body emits green light.

4. The light-emitting device according to claim 1- or 2, wherein the light-emitting layer further comprises a charge production layer arranged between every two adjacent second light-emitting bodies and between every two adjacent third light-emitting bodies, and the charge production layer is used for generating holes moving in a direction close to the cathode and electrons moving in a direction close to the anode under the action of an electric field between the cathode and the anode.

5. The light-emitting device according to claim 4, wherein the charge production layer covers only the second light-emitting bodies and the third light-emitting bodies, and the charge production layer is separated from the first light-emitting body.

6. The light-emitting device according to claim 4, wherein the charge production layer comprises a body, a first hole transport layer and a first electron transport layer, and wherein the first hole transport layer is arranged on a first side of the body close to the cathode, and the first electron transport layer is arranged on a second side of the body close to the anode.

7. The light-emitting device according to claim 6, wherein the charge production layer further comprises: a hole block layer, or an electron block layer, or a hole block layer and an electron block layer, wherein:
the hole block layer is arranged between a side of the first electron transport layer close to the anode and the second and third light-emitting bodies; and
the electron block layer is arranged between a side of the first hole transport layer close to the cathode and the second and third light-emitting bodies.

8. The light-emitting device according to claim 4, wherein the light-emitting structure further comprises an electron injection layer arranged on a side of the cathode close to the light-emitting layer, a second electron transport layer arranged between the electron injection layer and the light-emitting layer, a hole injection layer arranged on a side of the anode close to the light-emitting layer, and a second hole transport layer arranged between the hole injection layer and the light-emitting layer.

9. The light-emitting device according to claim 1, wherein a thickness of the first light-emitting body is greater than 5 nm and less than 100 nm.

10. The light-emitting device according to claim 9, wherein the thickness of the first light-emitting body is greater than 15 nm and less than 30 nm.

11. The light-emitting device according to claim 1, wherein a thickness of the first light-emitting body is identical to that of one of the at least two second light-emitting bodies.

12. The light-emitting device according to claim 1, wherein a thickness of the first light-emitting body is identical to that of one of the at least two third light-emitting bodies.

13. The light-emitting device according to claim 1, wherein the cathode is Mg:Ag, and the anode is indium tin oxide ITO/Ag/ITO arranged in a stacked manner.

14. A display panel, comprising the light-emitting device according to claim 1.

15. A display apparatus, comprising the display panel according to claim 14.

16. The light-emitting device according to claim 2, wherein the light-emitting layer further comprises a charge production layer arranged between every two adjacent second light-emitting bodies and between every two adjacent third light-emitting bodies, and the charge production layer is used for generating holes moving in a direction close to the cathode and electrons moving in a direction close to the anode under the action of an electric field between the cathode and the anode.

17. The light-emitting device according to claim 16, wherein the charge production layer covers only the second light-emitting bodies and the third light-emitting bodies, and the charge production layer is separated from the first light-emitting body.

18. The light-emitting device according to claim 16, wherein the charge production layer comprises a body, a first hole transport layer and a first electron transport layer, and wherein the first hole transport layer is arranged on a first side of the body close to the cathode, and the first electron transport layer is arranged on a second side of the body close to the anode.

19. The light-emitting device according to claim 18, wherein the charge production layer further comprises: a hole block layer, or an electron block layer, or a hole block layer and an electron block layer, wherein:
the hole block layer is arranged between a side of the first electron transport layer close to the anode and the second and third light-emitting bodies; and
the electron block layer is arranged between a side of the first hole transport layer close to the cathode and the second and third light-emitting bodies.

20. The light-emitting device according to claim 16, wherein the light-emitting structure further comprises an electron injection layer arranged on a side of the cathode close to the light-emitting layer, a second electron transport layer arranged between the electron injection layer and the light-emitting layer, a hole injection layer arranged on a side of the anode close to the light-emitting layer, and a second hole transport layer arranged between the hole injection layer and the light-emitting layer.
